(19) United States
(12) Patent Application Publication
(10) Pub. No.: US 2016/0233115 A1
(43) Pub. Date: Aug. 11, 2016

(54) CLEANING APPARATUS FOR SEMICONDUCTOR EQUIPMENT

(71) Applicant: HERMES-EPITEK CORPORATION, TAIPEI CITY (TW)

(72) Inventors: Chien-Ping HUANG, Tainan County (TW); Tsan-Hua Huang, Tainan City (TW); Tsung-Hsun HAN, Kaohsiung (TW); Kian-Poh WONG, Tainan City (TW)

(21) Appl. No.: 15/134,280

(22) Filed: Apr. 20, 2016

Related U.S. Application Data
(63) Continuation-in-part of application No. 14/018,928, filed on Sep. 5, 2013.
Application No. 14/018,928 is a continuation of application No. 13/856,092, filed on Apr. 3, 2013, now Pat. No. 8,719,993.
Application No. 13/856,092 is a division of application No. 12/726,183, filed on Mar. 17, 2010, now Pat. No. 8,448,288.
Application No. 12/726,183 is a continuation-in-part of application No. 14/703,113, filed on May 4, 2015.

(30) Foreign Application Priority Data
Feb. 1, 2010 (TW) 099102839
Feb. 12, 2015 (TW) 104104677

(51) Int. Cl. H01L 21/67; B08B 1/00; B08B 5/00; A46B 3/00; B08B 9/08; A46B 13/00; A46B 9/00; B08B 1/04; B08B 7/00

(52) U.S. Cl. CPC H01L 21/67046; B08B 1/04; B08B 1/002; B08B 5/00; B08B 7/0071; B08B 9/08; A46B 13/00; A46B 9/00; A46B 3/00; A46B 2200/3093

(57) ABSTRACT

A cleaning apparatus for a semiconductor equipment is provided. The cleaning apparatus comprising a cleaning pad with a plurality of brushes thereon is located on a rotor of the semiconductor equipment to remove residues within the semiconductor equipment by using the brushes against the residues via moving and rotating the rotor and the cleaning apparatus.

### CROSS-REFERENCE TO RELATED APPLICATIONS

This application is a CIP application of U.S. application Ser. No. 14/018,928, filed on Sep. 5, 2013 and entitled Semiconductor Equipment, which in turn is a continuation application of U.S. application Ser. No. 13/856,092, filed on Apr. 3, 2013 and entitled Semiconductor Equipment, which in turn is a divisional application of U.S. application Ser. No. 12/726,183, filed on Mar. 17, 2010 and entitled Semiconductor Equipment, which in turn claims the priority benefit of Taiwan Patent Application No. 099102839, filed on Feb. 1, 2010. This application is also a CIP application of U.S. application Ser. No. 14/703,113, filed on May 4, 2015 and entitled Wafer Holder, which in turn claims the priority benefit of TW Application No. 104104677, filed on Feb. 12, 2015. The entire contents of all of the foregoing applications are herein expressly incorporated by reference.

### BACKGROUND OF THE INVENTION

1. Field of the Invention

The present invention generally relates to semiconductor equipment, and more particularly to a cleaning apparatus applied on a semiconductor equipment to have a machine-maneuvered cleaning function.

2. Description of Related Art

Semiconductor manufacturing equipment is commonly used in the production of semiconductor components. The semiconductor manufacturing equipment typically has a reaction chamber. The reaction gases required by the semiconductor manufacturing process can be provided into the reaction chamber by a showerhead of the reaction chamber. The residues, such as deposited material or contaminants, may be attached within the reaction chamber after several executions of semiconductor manufacturing processes. Thus, process results and the process yields are affected by the residues.

Generally speaking, the residues within the reaction chamber can be removed by specific reaction gases. On the other hand, the residues within the reaction chamber can be removed manually when the reaction chamber is opened. However, using specific reaction gases to remove the residues within the reaction chamber is usually ineffective. Removing the residues within the reaction chamber manually with the reaction chamber opened usually leads to long maintenance times, inconsistent process results, and so on.

For the reason mentioned above, there is a need to propose a cleaning apparatus that can be integrated into said semiconductor equipment to have machine-maneuvered cleaning function. The semiconductor equipment should be capable of driving the cleaning apparatus to remove the residues within the reaction chamber.

### SUMMARY OF THE INVENTION

Accordingly, the present invention has been made in order to meet such a need as described above, it being an object of the present invention to provide semiconductor equipment a machine-maneuvered cleaning function. The semiconductor equipment is capable of removing residues within a reaction chamber with cleaning brushes.

In order to achieve the above object, the present invention provides a cleaning apparatus for semiconductor equipment. The semiconductor equipment includes a reaction chamber, a movable frame. The cleaning apparatus includes a cleaning pad with a plurality of brushes thereon. The brushes are disposed on the surface of the cleaning pad. The movable frame rotationally maneuvers the cleaning pad to remove the residues within the semiconductor equipment.

In one embodiment, the invention provides a method for cleaning a semiconductor equipment comprising the following steps first of all, a cleaning apparatus comprising a cleaning pad with a plurality of brushes on the cleaning pad is provided. Then the cleaning apparatus is placed on a movable frame of the semiconductor equipment. Finally, the cleaning apparatus and the movable frame are moved and rotated to remove residues within the semiconductor equipment by using the brushes against the residues, wherein the movable frame is configured to hold a susceptor for holding at least one wafer and the cleaning apparatus.

In another embodiment, the invention provides a semiconductor equipment with an in-situ cleaning function comprising a reaction chamber, a showerhead in the reaction chamber, a movable frame under the showerhead, a transmission device, and a cleaning apparatus comprising a cleaning pad with a plurality of brushes thereon. The transmission device is configured to linearly move and to rotate the movable frame. The movable frame is configured to hold a susceptor for holding at least one wafer and the cleaning apparatus, the cleaning apparatus is configured to be located on the movable frame to remove residues within the semiconductor equipment by using the brushes against the residues via moving and rotating the cleaning apparatus and the movable frame.

### BRIEF DESCRIPTION OF THE DRAWINGS

FIG. 1 is a schematic diagram illustrating a semiconductor equipment in accordance with a preferred embodiment of the present invention.

FIG. 2A is a schematic diagram illustrating the susceptor 230 holding a plurality of wafers 201 being loaded on the movable frame 220 by the fork 242 in FIG. 1 in accordance with an embodiment of the present invention.

FIG. 2B is a front view illustrating the susceptor 230 holding the wafers 201 being loaded on the movable frame 220.

FIG. 3A is a schematic diagram illustrating a cleaning pad 234 being loaded on the movable frame 220 by the fork 242 in FIG. 1 in accordance with an embodiment of the present invention.

FIG. 3B is a front view illustrating the cleaning pad 234 being loaded on the movable frame 220.

FIGS. 3C and 3D are schematic diagrams illustrating the brushes 236 in accordance with one embodiment of the present invention.

FIGS. 4A and 4B illustrate the cleaning pad 234 with the brushes 236 arranged to form triangle patterns in accordance with two embodiments of the present invention.

FIG. 5 depicts an in-situ cleaning operation via the cleaning pad 234 according to embodiments of the invention.

### DETAILED DESCRIPTION OF THE INVENTION

A detailed description of the present invention will be provided in connection with the following embodiments, which are not intended to limit the scope of the present invention and which can be adapted for other applications. While the drawings are illustrated in detail, it is appreciated that the quantity of the disclosed components may be greater or less than that disclosed except for instances expressly restricting the amount of the components.

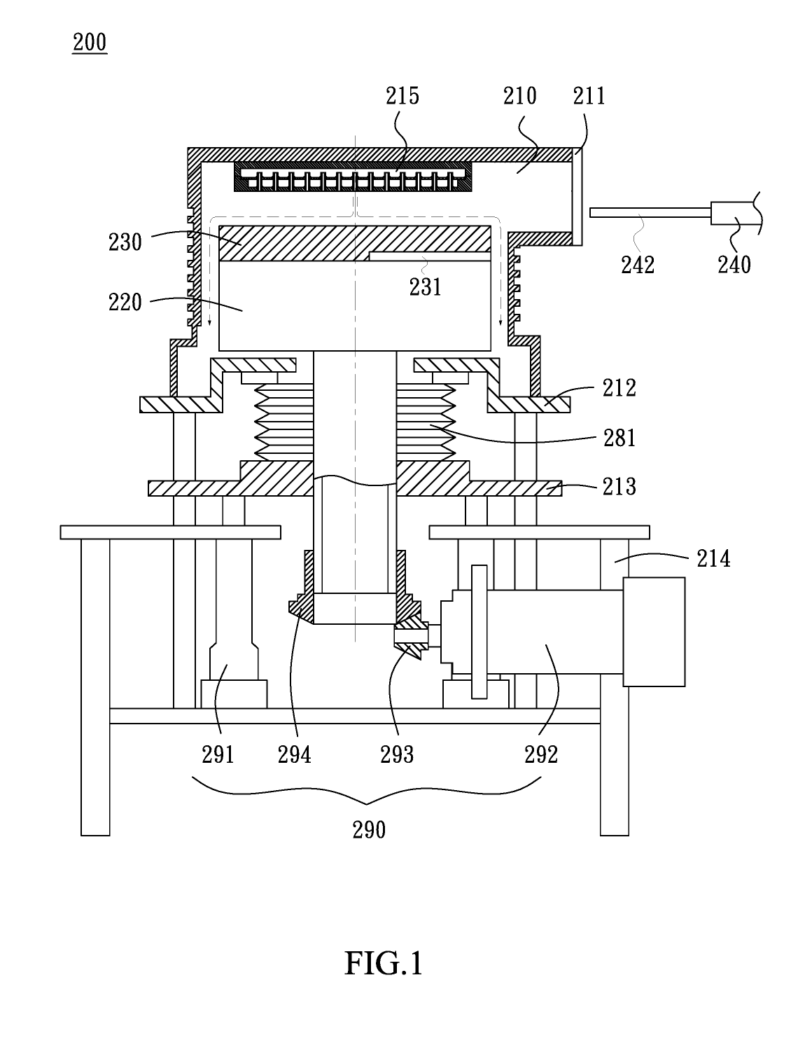

FIG. 1 is a schematic diagram illustrating semiconductor equipment 200 in accordance with a preferred embodiment of the present invention. The semiconductor equipment 200 includes a reaction chamber 210, a movable frame 220, and a robot arm 240 with a fork 242. The reaction chamber 210 in turn includes a showerhead 215. Hence, reaction gases required by the semiconductor manufacturing process can be provided into the reaction chamber 210 by way of the showerhead 215. The showerhead 215 is disposed on an upper portion of the reaction chamber 210. The movable frame 220 is disposed within the reaction chamber 210. The movable frame 220 is capable of carrying a susceptor 230. The susceptor 230 is capable of carrying at least one wafer. The movable frame 220 is able to make the susceptor 230 move vertically and/or rotate. The susceptor 230 comprises two stages 231 in the lower portion of the susceptor 230. The susceptor 230 can be disposed on the movable frame 220 via any suitable configuration, such as notches (not shown) in the movable frame 220 and protrusions (not shown) in the susceptor 230.

The semiconductor equipment 200 can further include a first frame 214, a second frame 213, a third frame 212, a transmission device 290, and a flexible catheter 281. The transmission device 290 in turn includes a linear transmission device 291. The linear transmission device 291 is disposed between the first frame 214 and the second frame 213. Hence, by way of the linear transmission device 291, the second frame 213 can move vertically relative to the first frame 214. The movable frame 220 is disposed on the second frame 213. When the second frame 213 moves vertically, the movable frame 220 also moves vertically. The flexible catheter 281 is disposed between the third frame 212 and the second frame 213. The flexible catheter 281 is used to prevent the gases within the reaction chamber 210 from leaking to the outside of the reaction chamber 210. The transmission device 290 includes a rotation transmission device. In this embodiment, the rotation transmission device includes a motor 292 and a gear assembly 293. Power from the motor 292 is transmitted to the movable frame 220 by the gear assembly 293 so as to make the movable frame 220 rotate.

The susceptor 230 can be loaded on or removed from the movable frame 220 by the robot arm 240 with the fork 242. In order to load and dispose the susceptor 230 on the movable frame 220, the fork 242 drove by the robot arm 240 extends into the stages 231 of the susceptor 230 so as to lift up the susceptor 230. Then the gate valve 211 is opened and the fork 242 carrying the susceptor 230 extends into the reaction chamber 210 to put the susceptor 230 on the movable frame 220. To remove the susceptor 230 from the movable frame 220, the fork 242 extends into the reaction chamber 210 after the gate valve 211 is opened. Then the fork 242 drove by the robot arm 240 extends into the stages 231 of the susceptor 230 so as to lift up the susceptor 230. Next the fork 242 carrying the susceptor 230 retracts from the reaction chamber 210. In order to load or remove the susceptor 230, the movable frame 220 may need to be moved vertically and to rotate so as to allow the fork 242 extending into the stages 231 of the susceptor 230.

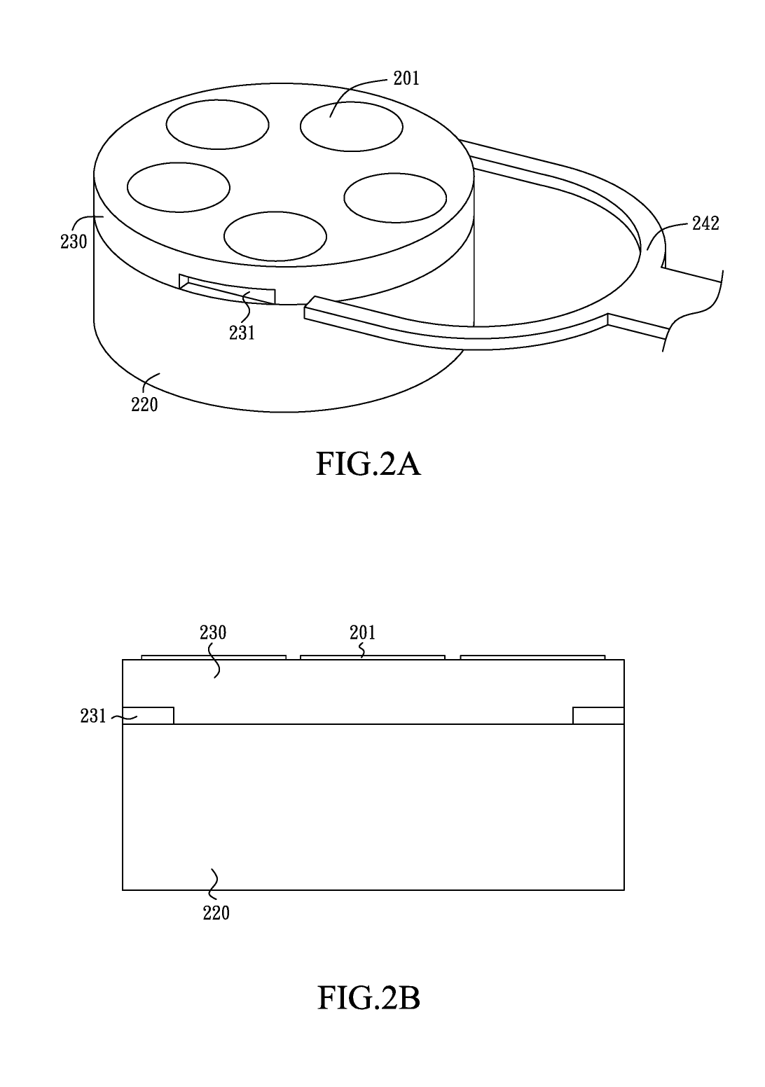

FIG. 2A is a schematic diagram illustrating the susceptor 230 holding a plurality of wafers 201 being loaded on the movable frame 220 by the fork 242 in FIG. 1 in accordance with an embodiment of the present invention. FIG. 2B is a front view illustrating the susceptor 230 holding the wafers 201 being loaded on the movable frame 220. As shown in FIG. 2A, the susceptor 230 is disposed on the movable frame 220 and the wafers 201 are loaded on the susceptor 230. The susceptor 230 can be loaded on or removed from the movable frame 220 by the fork 242. During loading or removing the susceptor 230, the fork 242 extends into the stages 231 of the susceptor 230 so as to lift up and move the susceptor 230.

Please referring back to FIG. 1, during the deposition process, reaction gases are delivered via the showerhead 215 to initiate deposition onto the wafers 201. However, possible residues also may be formed within the reaction chamber 210 during the deposition process. Particularly, residues resulting from various reasons such as non-uniform distribution of reacting gases or early reaction between reactants usually accumulate on the lower surface of the showerhead 215. Such undesired deposition consumes reactants and decreases the efficiency as well as the yield ratio, and the non-uniform deposition would further reduce the throughput of the process. Frequent cleaning, as a result, is usually required for the reaction chamber 210 and the showerhead 215.

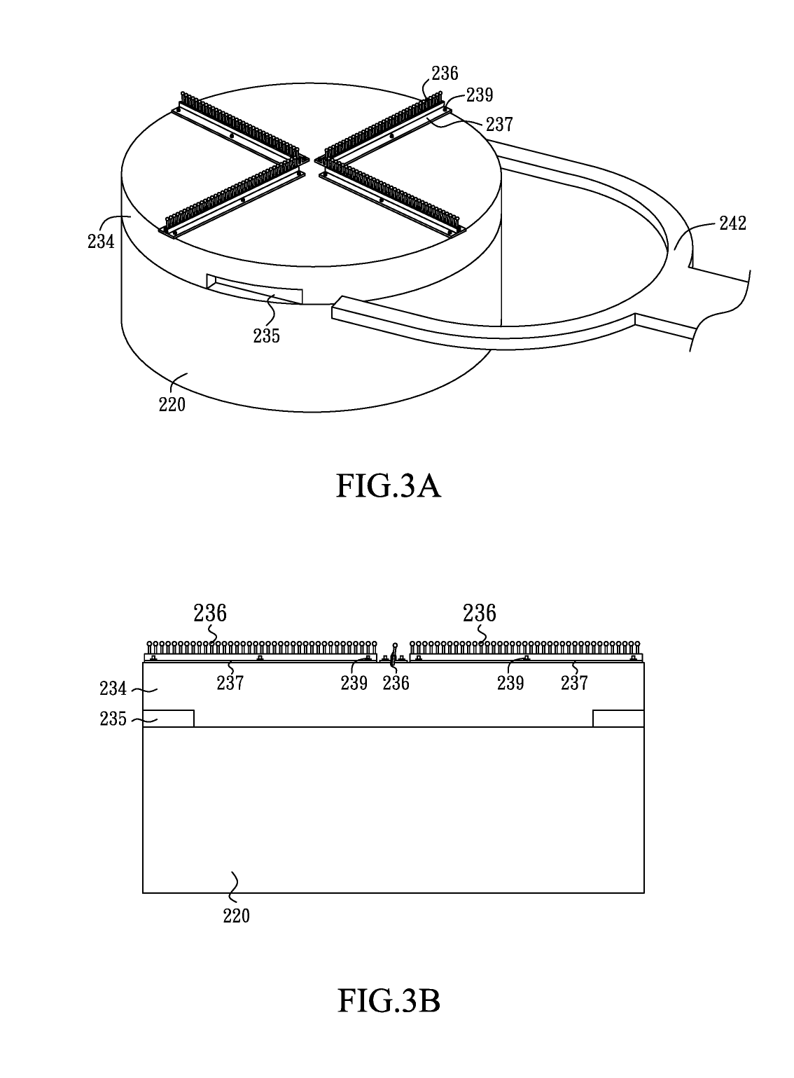

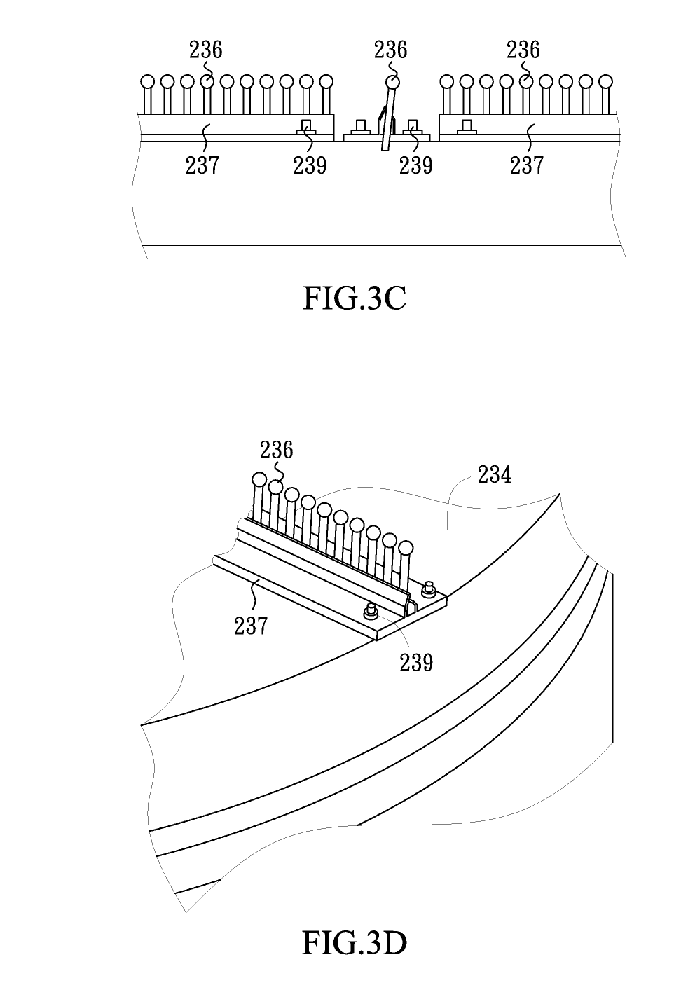

FIG. 3A is a schematic diagram illustrating a cleaning apparatus being loaded on the movable frame 220 by the fork 242 in FIG. 1 in accordance with an embodiment of the present invention. FIG. 3B is a front view illustrating the cleaning apparatus being loaded on the movable frame 220. The cleaning apparatus comprises a cleaning pad 234 with a plurality of brushes 236 thereon and two stages 235 in the lower portion of the cleaning pad 234. The cleaning apparatus can be disposed on the movable frame 220 via any suitable configuration, such as notches (not shown) in the movable frame 220 and protrusions (not shown) in the cleaning pad 234 similar to that of the susceptor 230. The material of the cleaning pad 234 comprises graphite and titanium, while the material of the brushes comprise stainless-steel and engineering plastics such as nylon. The cleaning pad 234 can be a graphite coated titanium pad. In one embodiment, the cleaning pad 234 has a shape of circular disk similar to the susceptor 230. In this embodiment, the brushes 236 are arranged to form a cross pattern with four brushes.

FIGS. 3C and 3D are schematic diagrams illustrating the brushes 236 in accordance with one embodiment of the present invention. The brushes 236 comprise a plurality of hairs disposed in slots of the cleaning pad 234. The hairs of the brushes 236 are further supported by strips 237 with a L shape cross section. The strips 237 can be mounted on the cleaning pad 234 via any suitable devices, such as screw nuts 239. In one embodiment, the brushes 236 are tilt brushes which can be achieved by the strips 237 with different L shape cross sections on two sides of the brushes 236. It is noted that the configuration, shape and material of the cleaning apparatus of the embodiment mentioned above and shown in FIGS. 3A to 3D are examples instead of limitations, any equivalents, alternatives or modifications of the embodiment corresponding to the spirit of invention should be encompassed in the scope of the invention.

Similar to the susceptor 230 shown in FIGS. 1 to 2B, the cleaning apparatus can be loaded on or removed from the movable frame 220 through the robot arm 240 with the fork 242. In order to load and dispose the cleaning pad 234 on the movable frame 220, the fork 242 drove by the robot arm 240 extends into the stages 235 of the cleaning pad 234 so as to lift up the cleaning pad 234. Then the gate valve 211 is opened and the fork 242 carrying the cleaning pad 234 extends into the reaction chamber 210 to put the cleaning apparatus on the movable frame 220. To remove the cleaning apparatus from the movable frame 220, the fork 242 extends into the reaction chamber 210 after the gate valve 211 is opened. Then the fork 242 drove by the robot arm 240 extends into the stages 235 of the cleaning pad 234 so as to lift up the cleaning apparatus. Next the fork 242 carrying the cleaning apparatus retracts from the reaction chamber 210. In order to load or remove the cleaning apparatus, the movable frame 220 may need to be moved vertically and to rotate so as to allow the fork 242 extending into the stages 235 of the cleaning pad 234.

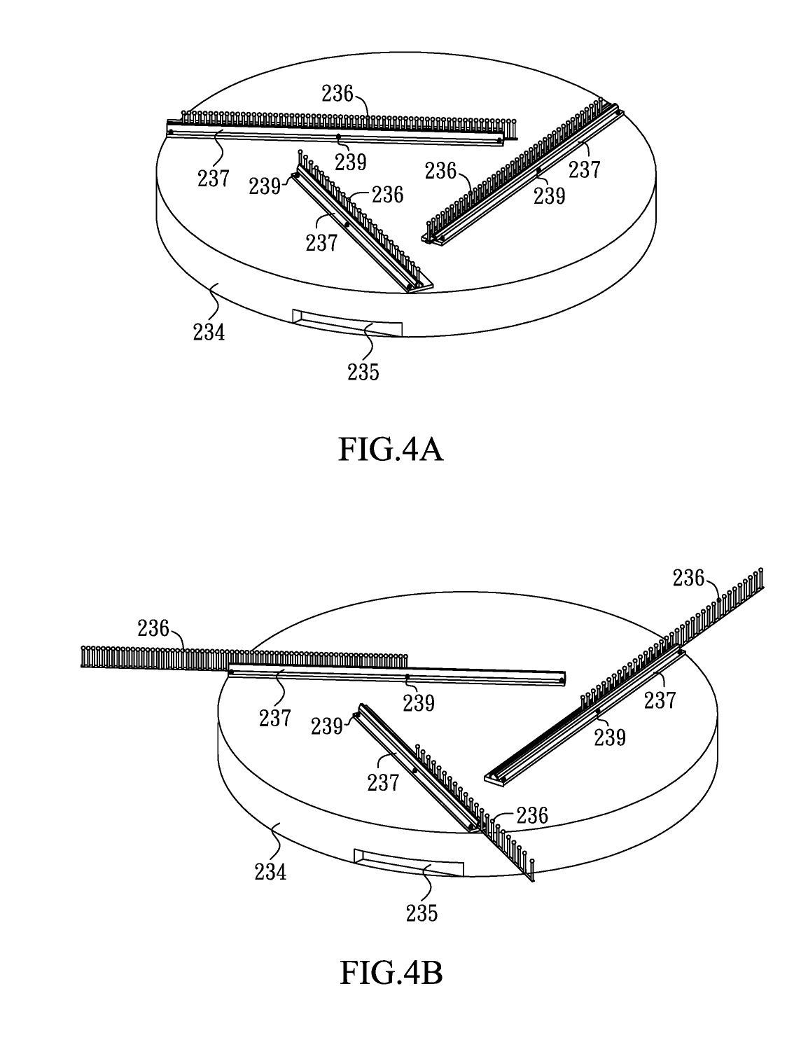

FIGS. 4A and 4B illustrate the cleaning pad 234 with the brushes 236 arranged to form triangle patterns in accordance with two embodiments of the present invention. As shown in FIGS. 4A and 4B, the cleaning pad 234 comprises three brushes 236 thereon, wherein the brushes 236 are arranged to form a triangle pattern. Moreover, the brushes 236 can extend outward to surpass the edge of the cleaning pad 234 so as to enlarge the cleaning range of the cleaning pad 234. It is noted that the number and arrangement of the brushes 236 on the cleaning pad 234 in these embodiments are examples instead of limitations, any equivalents, alternatives or modifications of the embodiment corresponding to the spirit of invention should be encompassed in the scope of the invention.

The present invention utilizes a cleaning apparatus comprising a cleaning pad with a plurality of brushes thereon to remove residues within a reaction chamber of a semiconductor equipment. The cleaning pad has a shape and a configuration similar to a susceptor for holding a wafer which can be loaded on a rotor or a movable frame in a reaction chamber by a robot arm with a fork. That is, the cleaning apparatus used as an in-situ cleaning tool can be loaded and held on a movable frame just like a susceptor. The cleaning apparatus can then be moved and rotated to lean against and to clean a showerhead inside the semiconductor equipment. More details about configurations and operations of the cleaning apparatus according to embodiments of the invention will be further described in the following contents.

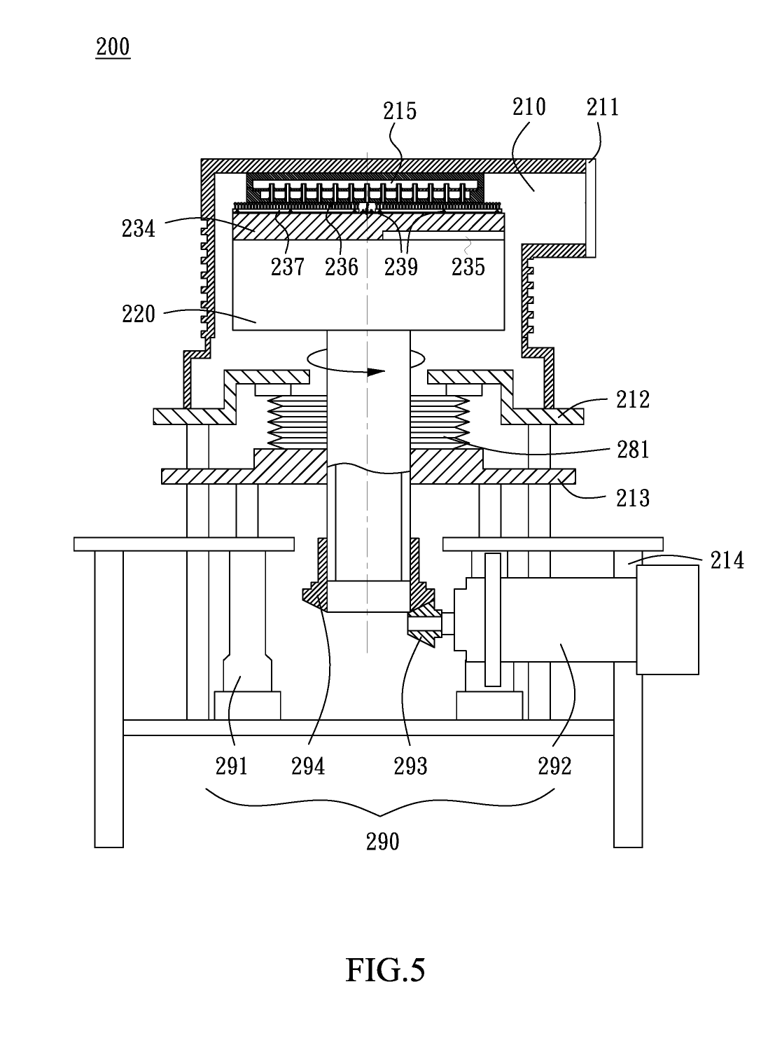

FIG. 5 depicts an in-situ cleaning operation via the cleaning apparatus according to embodiments of the invention. After deposition process, residues are usually formed within the reaction chamber. Particularly, many residues will accumulate on the lower surface of the showerhead 215. In this embodiment, the cleaning apparatus is used to remove residues on the showerhead 215. First of all, the cleaning apparatus is loaded and disposed on the movable frame 220 by the robot arm 240 with the fork 242. Then the movable frame 220 with the cleaning apparatus is moved linearly and vertically by the linear transmission device 291 of the transmission device 290 so that the brushes 236 on the cleaning pad 234 lean against the showerhead 215. Next the cleaning apparatus and the movable frame 220 are drove to rotate by the motor 292 and the gear assembly 293 so as to remove residues or other particles on the lower surface of the showerhead 215 and to clean the showerhead 215. Moreover, suitable purge gases can be delivered into the reaction chamber 210 through the showerhead 215 to purge out residues, particles, or contaminants, etc. Furthermore, a high temperature baking process can also be performed inside the reaction chamber 210 for a period of time to further remove remaining residues, particles, or contaminants, etc.

By employing the present invention, it provides the capability of removing residue attached within the reaction chamber without the need opening the reaction chamber for manual maneuver. As the result, maintenance time is decreased and the quality of manufacture is improved.

The present invention contemplates and provides a method for cleaning semiconductor equipment. Although specific embodiments have been illustrated and described, it will be appreciated by those skilled in the art that various modifications may be made without departing from the scope of the present invention, which is intended to be limited solely by the appended claims.

What is claimed is:

1. A cleaning apparatus for a semiconductor equipment, comprising:
a cleaning pad configured to be located on a movable frame of the semiconductor equipment; and
a plurality of brushes on the cleaning pad;
wherein the movable frame is configured to hold a susceptor for holding at least one wafer and the cleaning apparatus, the cleaning apparatus is used to remove residues within the semiconductor equipment by using the brushes against the residues via moving and rotating the cleaning apparatus and the movable frame.

2. The cleaning apparatus of claim 1, wherein the material of the cleaning pad comprises titanium, and the material of the brushes comprise stainless-steel.

3. The cleaning apparatus of claim 1, wherein the brushes are tilt brushes.

4. The cleaning apparatus of claim 1, wherein the brushes extend outward to surpass the edge of the cleaning pad.

5. The cleaning apparatus of claim 1, wherein the cleaning pad comprises stages in the lower portion of the cleaning pad.

6. The cleaning apparatus of claim 1, wherein the brushes on the cleaning pad are used to lean against and to clean a showerhead inside the semiconductor equipment.

7. The cleaning apparatus of claim 1, wherein the brushes are arranged to form a cross pattern with four brushes.

8. The cleaning apparatus of claim 1, wherein the brushes are arranged to form a triangle pattern with three brushes.

9. The cleaning apparatus of claim 1, wherein the cleaning pad comprises slots for accommodating the brushes.

10. The cleaning apparatus of claim 1, wherein the brushes are supported by strips with a L shape cross section.

11. A method for cleaning a semiconductor equipment, comprising:
providing a cleaning apparatus comprising a cleaning pad with a plurality of brushes on the cleaning pad;
placing the cleaning apparatus on a movable frame of the semiconductor equipment; and
moving and rotating the cleaning apparatus and the movable frame to remove residues within the semiconductor equipment by using the brushes against the residues, wherein the movable frame is configured to hold a susceptor for holding at least one wafer and the cleaning apparatus.

12. The method of claim 1, wherein the cleaning apparatus is placed on the movable frame by a fork drove by a robot arm and the fork is also used to place the susceptor on the movable frame.

13. The method of claim 1, wherein the brushes are used to clean a showerhead inside the semiconductor equipment.

14. The method of claim 13 further comprising a step of providing a purge gas into the reaction chamber through the showerhead to purge out the residues

15. The method of claim 14, wherein the movable frame is linearly moved and rotated by a transmission device of the semiconductor equipment.

16. A semiconductor equipment with an in-situ cleaning function, comprising:
a reaction chamber;
a showerhead in the reaction chamber;
a movable frame under the showerhead;
a transmission device, the transmission device being configured to linearly move and to rotate the movable frame; and
a cleaning apparatus comprising a cleaning pad with a plurality of brushes thereon, wherein the movable frame is configured to hold a susceptor for holding at least one wafer and the cleaning apparatus, the cleaning apparatus is configured to be located on the movable frame to remove residues within the semiconductor equipment by using the brushes against the residues via moving and rotating the cleaning apparatus and the movable frame.

17. The semiconductor equipment of claim 16, wherein the material of the cleaning pad comprises a graphite coated titanium pad, and the material of the brushes comprise engineering plastics.

18. The semiconductor equipment of claim 16, wherein the brushes are tilt brushes.

19. The semiconductor equipment of claim 16, wherein the cleaning pad comprises stages in the lower portion of the cleaning pad.

20. The semiconductor equipment of claim 19, wherein the stages are configured to allow a fork drove by a robot arm outside the reaction chamber to extend into the cleaning pad to lift up the cleaning apparatus.
